(19) United States
(12) Patent Application Publication
(10) Pub. No.: US 2025/0249767 A1
(43) Pub. Date: Aug. 7, 2025

(54) CONTACT RAIL ARRANGEMENT AND CHARGING METHOD

(71) Applicant: Stemmann-Technik GmbH, Schüttorf (DE)

(72) Inventor: Martin Brinker, Meppen (DE)

(73) Assignee: Stemmann-Technik GmbH, Schüttorf (DE)

(21) Appl. No.: 19/046,242

(22) Filed: Feb. 5, 2025

(30) Foreign Application Priority Data
Feb. 5, 2024 (DE) 102024103101.8

(51) Int. Cl. B60L 53/16; H05K 7/20

(52) U.S. Cl. CPC B60L 53/16; H05K 7/2089

(57) ABSTRACT

The invention relates to a contact rail arrangement 1 of a charging device for transmitting electrical energy to a current-carrying conductor of a vehicle, having a contact rail carrier 2 on which a contact rail 3 is arranged, wherein at least one electrical heating element 14 of a contact rail heater is arranged between the contact rail carrier 2 and the contact rail 3, wherein the heating clement 14 is a heating foil.

The invention relates to a contact rail arrangement with the features of claim 1 and a charging method according to claim 10.

Electrically powered vehicles, such as buses, can be charged while stationary, i.e. while they are stopped, by guiding a movable contact rail of a charging device, in particular from above, towards on-board electrical conductors. If the charging station and in particular the contact rail freeze over due to the weather, charging can be difficult or even impossible.

The invention is based on the object of demonstrating a contact rail arrangement for a charging device that can be used reliably even at low temperatures, in particular in freezing weather conditions. A suitable charging method is to be demonstrated that utilizes a contact rail arrangement of this kind.

The invention achieves this object by means of a contact rail arrangement with the features of claim 1 or 10.

The contact rail arrangement according to the invention comprises a contact rail carrier on which a contact rail is arranged for making contact with a current-carrying conductor on the vehicle side. The contact rail is a wearing part. The contact rail arrangement is configured such that the contact rail can be replaced regularly. It is therefore a detachable connection between the contact rail carrier and the contact rail.

According to the invention, at least one electric heating element of a contact rail heater is arranged between the contact rail carrier and the contact rail. The electric heating element is heated via a separate heating circuit. The contact rail heating system thus also includes a power source that is connected to the heating element, as well as a corresponding controller for the power source. The heating element is in contact with the contact rail and is used to keep the contact rail ice-free to ensure that adhering ice does not lead to an interruption of the electrical contact with a current-carrying conductor on the vehicle.

The at least one heating element is configured as a heating foil. In particular, only a single heating element and thus only a single heating foil is provided. One of the advantages of a heating foil is that it is particularly light and only marginally increases the weight of the contact rail arrangement. Heating foils are very thin and only a few millimeters thick, and usually thinner than 3 mm. They may be self-adhesive. They are flexible and can easily be adapted in their course of direction to curved contact rails.

The heating foil is arranged such that it is in contact with the contact rail, so that the heat from the heating element as a heat source is directly introduced into the contact rail and prevents ice from forming on the contact rail. It is important that the contact between the heating foil and the contact rail is as large as possible. The larger the contact area between the heating surface and the contact rail, the more likely it is that heating foils with a lower heating output can be used.

In order to establish the close and preferably full-surface contact, the heating element or heating foil can be preferably arranged in the area of a contact rail carrier contact surface for the contact rail. In a first embodiment of the invention, a recess is formed in a contact surface of the contact rail carrier, in which the at least one heating element is arranged. The heating element or heating foil may protrude slightly beyond the contact surface so that it is pressed firmly against the contact rail when the contact rail is mounted. As a result, the contact rail lies as flat as possible against the heating element or heating foil. The recess also allows for thicker or more powerful heating elements or heating foils, or even more pressure-sensitive heating elements, to be installed. The contact surface or the surrounding edge area outside the recess serves as the contact surface between the contact rail carrier and the contact rail. In all embodiments, an insulator may be arranged on the contact rail carrier for the thermal insulation of the at least one heating element, so that the heat is transferred to the contact rail and not to the contact rail carrier. An insulator may be arranged in the recess. The contact rail carrier itself may be made of a thermally insulating material.

Alternatively, the heating element can be held without a recess in the contact rail carrier, sandwiched between the contact surface and the contact rail. In this case, the contact rail is not in direct contact with the contact surface, but with the heating element. This type of fastening has the advantage of holding the heating element or film extremely securely and firmly, while at the same time keeping it in close contact with the contact rail, thus ensuring an excellent heat transfer.

The heating element is most effective when the heat flow can be conducted into the contact rail over a large surface. Therefore, the heating element should extend across the contact rail at least 90% of its length, and preferably across the entire length of the contact rail. Similarly, the heating element should extend across at least 50% of the width measured across the length of the contact rail, in particular across 70 to 80, preferably 100%, of the width of the contact rail, as far as technically possible.

To mount the contact rail on the contact rail carrier, fasteners are required, typically in the form of bolts that penetrate through the contact rail. Accordingly, it is advisable to provide openings in large heating elements to accommodate the fasteners used to fasten the contact rail on the contact rail carrier. When the fasteners, in particular screws, also penetrate through the openings in the heating elements, they also fix the heating elements in place, so that they are always held on the contact rail arrangement in an non-detachable and correctly positioned manner. In addition, the arrangement of the heating elements between the contact rail and the contact rail carrier means that they are always protected from damage and external influences.

Depending on the configuration of the contact rail carrier, the contact rail may protrude with a narrow side opposite the contact rail carrier. Contact with the current-carrying conductor is then made via the protruding area of the narrow side. Such a contact rail usually has a essentially rectangular cross-section. The maximum heat input can be applied across the broadside, which preferably faces the front of the contact rail carrier. Accordingly, the at least one heating element, in particular a heating foil, is arranged between the front side of the contact rail carrier and the broadside of the contact rail. The heating foil cannot be damaged due to this arrangement, even if the wear limit of the contact rail has been reached.

In a further development of the invention, the contact surface against which the contact rail rests can rebound from the front side of the contact rail carrier to such an extent that a pocket is formed in which the contact rail is arranged. This makes it possible to use lighter and more compact contact rail carriers. The rebounding contact surface further increases the protection of the at least one heating element against external influences, since the heating element itself is also arranged in the pocket. If one narrow side of the contact rail protrudes from the contact rail carrier, it is preferably an arrangement in which the contact surface is vertical. The contact surface of the contact rail with an electrical conductor is perpendicular to the contact surface and therefore runs horizontally across the direction of travel of the vehicle.

In an alternative embodiment of the invention, the contact surface itself is horizontal, whereby the contact rail is adjacent to it in the vertical direction. The advantages described above also apply to this embodiment in a figurative sense. The flat heating element, preferably a heating foil, is located horizontally between the contact rail and the contact rail carrier. In the same way, a heating element of this type may have openings for receiving fasteners. Even with horizontal contact surfaces, the heating elements should extend across the greatest possible surface of the contact rail, i.e. across preferably at least 90% of the length and at least 50%, preferably 80%, of the width, whereby the heating element should take up the same surface as the contact rail in order to maximize the surface for heat transfer.

The charging method according to the invention is based on the use of the contact rail arrangement described above. The stationary charging device has the aforementioned contact rail arrangement for transmitting electrical energy to a current-carrying conductor of a vehicle. In particular, the charging device is a lowering unit, such as a pantograph, for example, which is lowered from above towards the roof-mounted current-carrying conductors of a vehicle and in doing so brings the contact rail arrangement into electrically conductive contact with the vehicle in order to charge its energy storage. Even before charging, the system ensures that charging is not impeded by the formation of ice by heating the contact rail with the electric heating element of the contact rail heater before contact is made. Heating can be activated by means of a temperature sensor that measures the ambient temperature. As soon as the temperature falls below freezing, a control unit can cause the contact rail to be heated. Heating can be time-controlled or proximity-controlled, i.e. when a vehicle approaches or is announced for charging, or motion-controlled, e.g. when the contact rail is moved, or it can be done at regular intervals or at specific times of day. It is also possible that by means of optical detection of the icing or an ice load monitoring system that takes the weight into account, possibly in conjunction with weather data and/or with the help of empirical values or with the help of an AI, an adaptive adjustment of the switch-on times and switch-on duration takes place so that the charging device is ready for use at the desired time. It is also possible to switch the contact rail heating on and off manually.

In the following, the invention will be described in greater detail with reference to exemplary embodiments illustrated in schematic drawings. In particular:

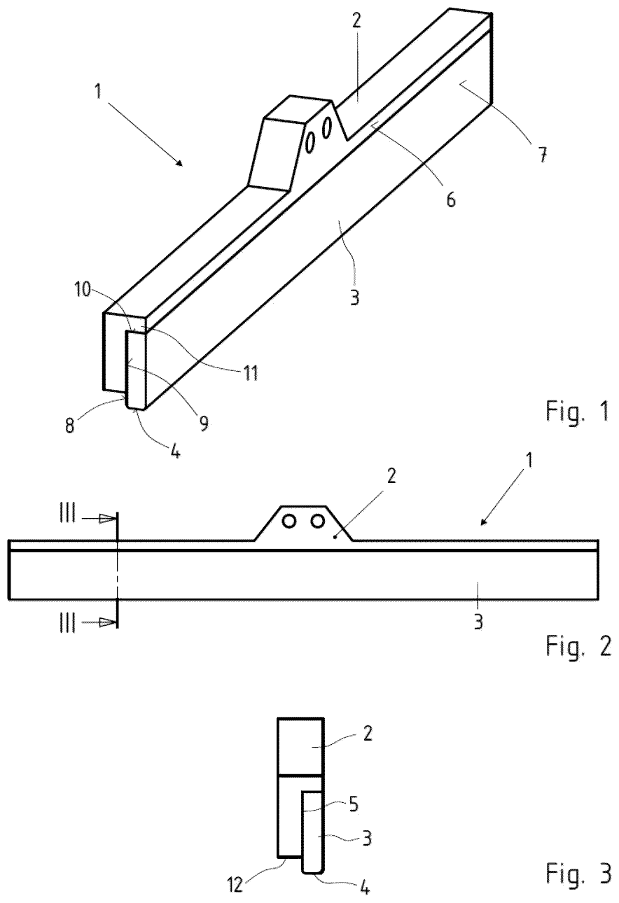

FIG. 1 shows a perspective view of a contact rail arrangement;

FIG. 2 shows the contact rail arrangement of FIG. 1 in a front view;

FIG. 3 shows the contact rail arrangement of FIGS. 1 and in a section along the line III-III in FIG. 2;

FIGS. 4 to 6 each show variants of a contact rail arrangement in a view according to section line III-III in FIG. 2;

FIG. 7 shows another embodiment of a contact rail arrangement in cross-section.

FIG. 1 shows a contact rail arrangement 1 of a charging device (not shown in detail) for charging an electrically powered vehicle. The charging device is configured to bring the contact rail arrangement 1 into electrically conductive contact with conductors on the vehicle. The contact rail arrangement 1 is mounted on the charging device in such a way that the on-board current-carrying conductor is essentially perpendicular to the contact rail arrangement 1.

The contact rail arrangement 1 has a contact rail carrier 2, which is connected to the charging device, and a contact rail 3, which is provided for contact with the on-board current-carrying conductor and is connected to the contact rail carrier 2 in a manner not shown in more detail, in particular screwed via several screw elements. FIGS. 2 and 3 show the contact rail arrangement 1 in front view and in cross-section.

The contact rail 3 is cuboid in cross-section and has a narrow side 4 that protrudes in the image plane downwards over the contact rail carrier 2. This is the contact side with which the contact rail 3 comes into contact with the electrical conductor. The contact rail 3 is exactly as long as the contact rail carrier 2. The contact rail 3 is also located in a pocket 5, so that the contact rail 3 does not protrude over the front side 6 of the contact rail carrier 2. The contact rail 3 ends at the front with the front side 6 of the contact rail carrier 2. In an alternative embodiment, the contact rail 3 can protrude over the front side 6. The contact rail 3 has a front side 7, which is configured as a broadside. Opposite the front side 7 is the rear side 8 of the contact rail 3, which is arranged on a rebounding contact surface 9 within the pocket 5. In the vertical direction, the upper narrow side 10 of contact rail 3 is supported on a web 11 of the pocket. The pocket 5 is, as it were, a notch or corner recess of the contact rail carrier 2, so that the pocket 5 is open towards the front side 6 of the contact rail carrier 2 and towards its underside 12, which is at the bottom of the image page.

FIGS. 4 to 6 show different embodiments of such contact rail arrangements 1 corresponding to sectional plane III-III in FIG. 2. In FIG. 4, there is additionally a recess 13 within the contact surface 9. Arranged within the flat recess 13 is a heating element 14, which is connected in a manner not shown in more detail to a contact rail heater. The term contact rail heater includes the means of controlling and supplying power to the electric heating element. The electric heating element 14 can be switched on and off as required. It can be supplied with more or less electrical energy as needed to adjust the heating output according to the weather.

FIG. 4 shows an example of an implementation in which the heating element 14 is protected to the maximum extent and is not exposed to any environmental influences.

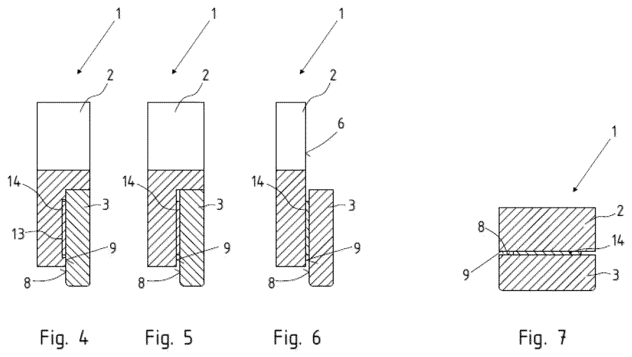

In an alternative configuration in accordance with FIG. 5, the recess 13 was omitted. The heating element is sandwiched between the back 8 of the contact rail and the contact surface 9. In a manner not described in more detail, the respective heating element 14 substantially extends across the entire length of the contact rail 3 and the length of the contact rail holder 2.

The exemplary embodiment of FIG. 6 differs from that of FIGS. 4 and 5 in that the configuration of a pocket inside the contact rail carrier 2 has been omitted. As a result, the contact rail carrier 2 is considerably narrower overall and therefore also lighter. The dimensions of the contact rail 3 have remained identical. The heating element 14 is also identical. It is once again sandwiched between the back side 8 of the contact rail and the contact surface 9, which in this case does not rebound but coincides with the front side 6 of the contact rail carrier 2.

While the contact surface 9 is always oriented vertically in the embodiments of FIGS. 1 to 6, an alternative design embodiment according to FIG. 7 provides that the contact rail carrier 2 is arranged horizontally at the top in the image plane, having a horizontal contact surface 8, whereby the rear side 9 of the contact rail 3 is also arranged horizontally and is aligned parallel to the contact surface 8. The contact rail 3 has the same width and length as the contact rail carrier 2. The reference numerals already introduced in FIGS. 1 to 6 are used for components with the same function. Another flat heating element 14 is located between the rear side 9 of the contact rail 3 and the contact surface 8 of the contact rail carrier 2, in particular in the form of a heating foil. In terms of function, this design corresponds to that of FIGS. 5 and 6, only the dimensions of contact rail 3 are different, as is the fastening direction between contact rail carrier 2 and contact rail 3.

### Reference Numerals

1—contact rail arrangement
2—contact rail carrier
3—contact rail
4—narrow side of 3
5—pocket in 2
6—front side of 2
7—front side of 3
8—back side of 3
9—contact surface of 2
10—upper narrow side of 3
11—web
12—underside of 2
13—recess in 9
14—heating element

1. A contact rail arrangement of a charging device for transmitting electrical energy to a current-carrying conductor of a vehicle, having a contact rail carrier on which a contact rail is arranged, wherein at least one electrical heating element of a contact rail heater is arranged between the contact rail carrier and the contact rail, characterized in that the at least one heating element is configured as a heating foil which is in contact with the contact rail.

2. The contact rail arrangement of claim 1, wherein the contact rail carrier has a contact surface for the contact rail wherein a recess is formed in the contact surface, in which the at least one heating element is arranged.

3. The contact rail arrangement of claim 1, wherein the contact rail carrier has a contact surface for the contact rail wherein the at least one heating element is sandwiched between the contact surface and the contact rail.

4. The contact rail arrangement of claim 1, wherein the at least one heating element extends across at least 90% of the length of the contact rail.

5. The contact rail arrangement of claim 1, wherein the at least one heating element extends across at least 50% of the width measured transversely to the length of the contact rail.

6. The contact rail arrangement of claim 1, wherein the at least one heating element has openings for receiving fasteners with which the contact rail is fastened to the contact rail carrier.

7. The contact rail arrangement of claim 1, wherein the contact surface rebounds relative to a front side of the contact rail carrier to such an extent that a pocket is formed, in which the contact rail is arranged.

8. The contact rail arrangement of claim 1, wherein the contact surface runs vertically.

9. The contact rail arrangement of claim 1, wherein the contact surface runs horizontally, wherein the contact rail is located vertically adjacent to the contact rail carrier.

10. A charging method using a contact rail arrangement of on a charging device for transmitting electrical energy to a current-carrying conductor of a vehicle, wherein the electrical heating element of the contact rail heater heats the contact rail before the contact rail coming from the charging device from above is brought into contact with a current-carrying conductor arranged on the roof.
